(19) United States
(12) Patent Application Publication
(10) Pub. No.: US 2005/0111368 A1
(43) Pub. Date: May 26, 2005

(54) Method and system for dynamic tariffing

(75) Inventors: Wilhelm Werner Meincke, Ratingen (DE); Tobias Weidhase, Dusseldorf (DE)

Correspondence Address: MICHAELSON AND WALLACE;PARKWAY 109 OFFICE CENTER, 328 NEWMAN SPRINGS RD, P O BOX 8489, RED BANK, NJ, 07701, US

(73) Assignee: Koninklijke KPN N.V.

(21) Appl. No.: 10/979,081

(22) Filed: Nov. 1, 2004

Related U.S. Application Data
(60) Provisional application No. 60/516,570, filed on Oct. 31, 2003.

(51) Int. Cl. G01R 31/08

(52) U.S. Cl. 370/235.1; 379/114.02

(57) ABSTRACT

The invention relates to a method and a system for dynamic tariffing of telecommunication services. It uses a leakage bucket storage module (1) for handling a current tariff variable (LB_C); an inflow control module (2) for controlling the increase (LB_A) of the current tariff variable (LB_C); and an outflow control module (3) for controlling the decrease (LB_B) of the current tariff variable (LB_C).

### FIELD OF THE INVENTION

The invention related to a system for dynamic tariffing of telecommunication services, the system comprising at least one computer. The invention further relates to a method for dynamic tariffing of telecommunication services in at least one computer comprising one or more modules.

### BACKGROUND

In telecommunications tariffing methods are known where frequent usage of telecommunication services is rewarded with bonuses, discounts or cheaper tariffs. Calculation of tariffs is commonly based on time units, like day, week or month. E.g. when sending SMS messages in GSM the tariff can become lower or a bonus can be rewarded when sending more then 10 SMS messages within 24 hours. Each day the tariff calculation algorithm starts again.

A disadvantage of existing tariffing methods is the inflexible usage of time units. Known tariffing solutions often make use of monthly calculations. On receiving the bill customers can then monthly check whether the tariffs of telecommunication services are satisfactory or the usage of telecommunication services should change in order to have a better tariff. Especially with prepaid telecommunication services it is common to have such a monthly tariffing algorithm.

### AIM OF THE INVENTION

It is the aim of the invention to overcome the disadvantages of the background and enable dynamic and flexible tariffing.

### SUMMARY OF THE INVENTION

The present invention provides a solution for dynamic and flexible tariffing.

According to an aspect of the invention a system for dynamic tariffing of telecommunication services is provided, where the system comprising at least one computer, the at least one computer comprising a leakage bucket storage module for handling a current tariff variable; an inflow control module for controlling the increase of the current tariff variable; an outflow control module for controlling the decrease of the current tariff variable; the inflow control module being arranged to communicate with the leakage bucket storage module via a first interface and the outflow control module being arranged to communicate with the leakage bucket storage module via a second interface. An advantage of this system is that the current tariff that is applicable to current usage of telecommunication services by the customer, can dynamically be set and controlled.

The inflow control module can comprise a third interface to receive service information data and a fourth interface to receive weighing parameters to weigh the service information data, the weighted service information data controlling the increase of the current tariff variable. This enables a flexible control of the increase of the current tariff variable, based on input data like e.g. the number of voice calls made. By weighing the service information data different kind of input data can be given a different impact on the increase.

The outflow control module can comprise a fifth interface to receive subscription conditions data, the subscription conditions data controlling the decrease of the current tariff variable. This enables a flexible control of the decrease of the current traffic variable, based on e.g. the kind of subscription of a customer.

The at least one computer can further comprise a tariff definition module for reading the current tariff variable, the tariff definition module being arranged to communicate with the leakage bucket storage module via a sixth interface, the tariff definition module further being arranged to communicate with an external rating engine via a seventh interface. This enables external systems to use the current tariff variable.

The at least one computer can further comprise a direct modification module for directly setting the current tariff variable to a specific value, the direct modification module being arranged to communicate with the leakage bucket storage module via a eighth interface, the direct modification module further being arranged to communicate with a service provider system via a ninth interface. This enables a service provider to set the current tariff value to a value independent of the inflow control module and independent of the outflow control module.

The at least one computer can further comprises an info push module for preparing and pushing informative messages to a customer through a tenth interface, the info push module being arranged to communicate with the leakage bucket storage module via a eleventh interface. This enables the system to send informative messages indicating the current tariff at its own initiative.

The at least one computer can further comprise an info access module for providing the current tariff variable when a request is received through a twelfth interface, the info access module being arranged to communicate with the leakage bucket storage module via a thirteenth interface. This enables the system to send informative messages indicating the current tariff on request.

According to a second aspect of the invention a method is provided for dynamic tariffing of telecommunication services in at least one computer comprising one or more modules, the method comprising the steps of handling a current tariff variable; controlling the increase of the current tariff variable; controlling the decrease of the current tariff variable. An advantage of this method is that the current tariff that is applicable to current usage of telecommunication services by the customer, can dynamically be set and controlled.

The method can comprise using a weighted service information data for controlling the increase of the current tariff variable. This enables a flexible control of the increase of the current tariff variable, based on input data like e.g. the number of voice calls made. By weighing the service information data different kind of input data can be given a different impact on the increase.

The method can comprise using a subscription conditions data for controlling the decrease of the current tariff variable. This enables a flexible control of the decrease of the current traffic variable, based on e.g. the kind of subscription of a customer.

The method can comprise reading and sending the current tariff variable to an external rating engine via a seventh interface. This enables external systems to use the current tariff variable.

The method can comprise directly setting the current tariff variable to a specific value. This enables a service provider to set the current tariff value to a value independent of the inflow control module and independent of the outflow control module.

The method can comprise preparing and pushing informative messages to a customer through a tenth interface. This enables the system to send informative messages indicating the current tariff at its own initiative.

The method can comprise providing the current tariff variable when a request is received through a twelfth interface. This enables the system to send informative messages indicating the current tariff on request.

### BRIEF DESCRIPTION OF THE DRAWINGS

The invention will be explained in greater detail by reference to exemplary embodiments shown in the drawings, in which:

FIG. 1 shows a leakage bucket model;

FIG. 2 shows an architectural overview of the system.

### DETAILED DESCRIPTION OF THE INVENTION

For the purpose of teaching of the invention, preferred embodiments of the method and system of the invention are described in the sequel. It will be apparent to the person skilled in the art that other alternative and equivalent embodiments of the invention can be conceived and reduced to practice without departing from the true spirit of the invention, the scope of the invention being only limited by the claims as finally granted.

Advantageous for prepaid, but also useable for postpaid contracts, is an automatic adaptation of tariffs that is based on the average usage by the customer and information about the real time actual tariff and that is independent of fixed time units. Tariffing using the principle of “leakage bucket” offers the customer a tariff concept that automatically calculates the actual tariff from the service usage. Moreover it enables the customer to get informed about the current actual tariff immediately.

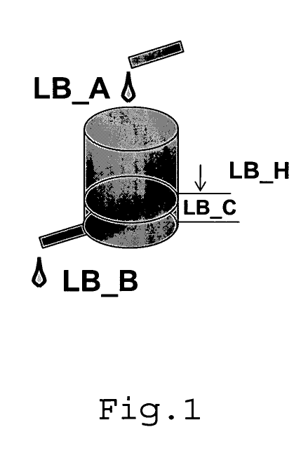

In FIG. 1 a leakage bucket is shown. The principle of the leakage bucket is used to calculate tariffs. Characteristic for the leakage bucket is that a virtual fill-level is stored per customer in a service platform. The fill-level is altered by an in software implemented algorithm running on a computer. The fill-level represents the actual tariff, i.e. the actual costs for telecommunication services for the customer.

The fill-level is calculated as follows:
LB_{—}C=LB_{—}A(i)−LB_{—}B(t), with 0<=LB_{—}C<=LB_{—}H

The variables are used as follows:
LB_C: the current fill-level of the leakage bucket
LB_H: the maximum fill-level
LB_A (i): filling of bucket because of used services (in-flow)
LB_B (t): constant reduction of fill-level (out-flow)

The maximum fill-level LB_H is divided into ‘n’ parts. The current tariff for telecommunication services is determined by the current fill-level LB_C, i.e. the current part of LB_H that the fill-level is in. E.g. if n=3, the following derivation of tariffs can be made:
0<=LB_C<LB_H/3 . . . Tarif 1
LB_H/3<=LB_C<2 LB_H/3 . . . Tarif 2
2 LB_H/3<=LB_C<=LB_H . . . Tarif 3
   Logically Tarif 1>Tarif 2>Tarif 3.

The fill-level is based on services and its service characteristics, like costs made by the customer, events (e.g. the number of phone calls made), the time spend by a customer on services, or a combination of these.

Examples of services are:
Phone calls (incoming or outgoing);
SMS or MMS messages;
GPRS Data traffic;
Content Access.

Examples of service characteristics are:
time spend;
costs made;
volume used;
events done.

Weighing of a service (i.e. the strength of the in-flow) is flexibly derivable using tables. E.g. incoming calls from a fixed network (i.e. calls to the customer from a phone in a fixed telecommunications network) can be rated higher, thus resulting in a larger in-flow.

Bonus or promotion offerings can increase the in-flow or change fill-level to another level. E.g. on the customer's birthday the fill-level is set to the next favorable level. The customer is informed about this by USSD or SMS message. A specific algorithm can monitor the fill-level and trigger bonus actions at specific levels.

The out-flow is defined by the customer's subscription. E.g. the amount of handset subsidy is used to define the out-flow.

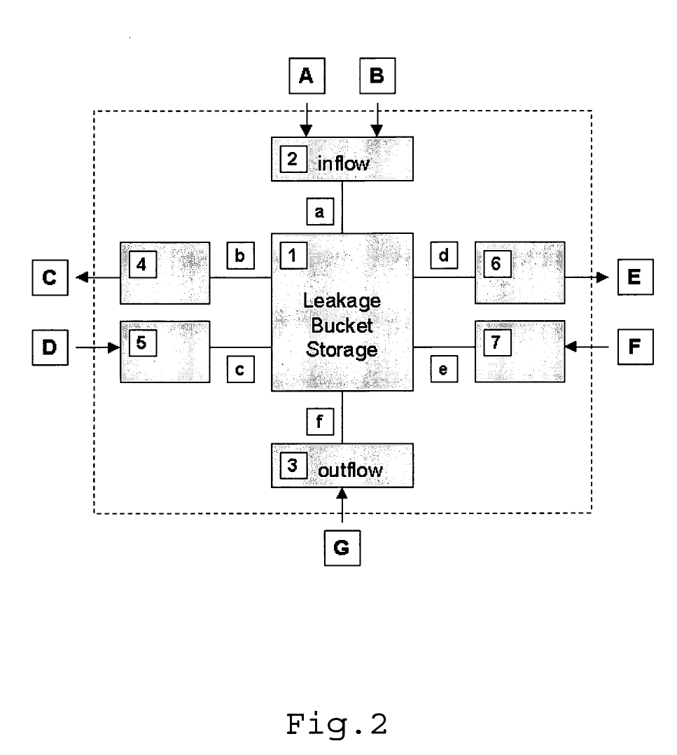

FIG. 2 shows an exemplary embodiment of the invention. Other embodiments are possible where one or more modules are left out. It is also possible that the functionality as described below differs in other embodiments, based on the text above.

Overview of the Modules as implemented in one or more computers according to the exemplary embodiment:
1. Leakage Bucket Storage Module
   The fullness of the “Bucket” represents the current tariff for the usage of telecommunication services for a certain subscriber.
2. “Inflow” Control Module
   Controls the “”inflow” of the “Bucket”.
3. “Outflow” Control Module
   Determines the “outflow” of the “Bucket”.
4. Info Push Module
   Recognise the transitions to different stages in the “Bucket” and inform the user about these events by e.g. by SMS, USSD, WAP Pushes.
5. Info Access Module
   Displays the status of the “Bucket” in case of user request by e.g. i-mode™, web, SMS, Voice, USSD or other known methods.
6. Tariff Definition Module
   Defines the current tariff for telecommunication services based on the present fullness in the Bucket and makes it available for an external rating engine.
7. Direct Modification Module
   Allows the modification of the fullness directly e.g. sets the level in the “Bucket” to the next better tariff representation in case of certain events/bonuses.

For each module a functional description will be given.

Leakage Bucket Storage Module [1]

The Leakage Bucket Storage Module [1] is the central functional module in the arrangement of the modules [2]-[7]. This module comprises a counter part, a configuration part and a runtime part.

The counter part consists of a counter, which counts units individually for one subscriber or individually for a group of subscribers. A unit is the smallest entity, which represents the usage of telecommunication services of a subscriber or a group of subscribers. The meaning of a unit/of units are configurable (e.g. 1 call minute to a destination in the home network is equal to x units) and is defined by the Inflow Control Module [2]. The value of the counter is related to a certain “level of filling in the Bucket”. This level represents the current tariff (e.g. the call in the home network cost xyz Euro per minute) for usable telecommunication services by a subscriber or by a group of subscribers and is determined by the Tariff Definition Module [6].

The configuration part allows the “form” and the settings of the bucket. It determines
the maximum of the counter value
the relation between the amount of units (=value of the counter) and the “level of filling” in the Bucket, this can be equal, linear, exponential or other applicable mathematical function (note: means visually, the diameter of the bucket can be a function of the height of the bucket).
Up to n sub-levels (n can be an integer greater 0), which define areas with different amount of units whereas one area of filling level is assigned to one tariff representation. The distance between the sub-levels can be equidistantly, can be follow a mathematical function or can be defined arbitrarily.

The runtime part of the Leakage Bucket Storage Module increases respectively decreases the counter of the counter part, calculate the level of fullness of the bucket derived from the present value of the counter, limits the counter value to the configured maximum, observe the transitions between of the filling level and the configured sub-levels, stores reports subscriber individually or group individually in a data base and acts to the other modules by supporting the interfaces [a] to [f] (description of these interfaces see the description of modules [2] to [7]).

Inflow Control Module [2]

The Inflow Control Module [2] controls the inflow for the Leakage Bucket Storage Module [1] using the interface [a] by computing the input data from the external interfaces [A] and [B].

External Interface [A] supplies service information data, which presents telecommunications service usage or events or non-telecommunications events from/for the subscriber or a group of subscribers. The Inflow Control Module receives the data and calculate the appropriate units for the Leakage Bucket Storage Module [1].

Telecommunication service usage data can be (examples)
output of an external rating engine (e.g. cost of the last call was xyz Euro)
CDR (Call Data Record) contents e.g. the duration, the destination, . . . of a call
SDR (Service Data Record) contents the specific usage of a service
EDR (Event Data Record) informs about specific events
other usage data contents . . .

Services can be
Voice Calls
Data sessions

Usage can be
duration of a call measured in minutes
volume of data sessions

Telecommunication events can be (examples)
bonus points from the service or network provider
subscription of a i-mode™ content subscription

Non-Telecommunication events can be (examples)
bonus points from an airline company

The external interface [B] delivers parameter to weight the input parameter supplied by interface [A] resulting in a modification of the rules for generating units for the Leakage Bucket Storage Module [1]. For example incoming calls from the national networks could be weighted higher than the outgoing calls or the service or network provider can determine that the next 10 SMS are free/cheaper. The latter case can be aligned with a timeframe e.g. the next 10 SMS are free/cheaper till at the end of the day, weekend or month.

Outflow Control Module [3]

The Outflow Control Module [3] controls the outflow for the Leakage Bucket Storage Module [1] using the interface [f] by decreasing the units in the counter of the Leakage Bucket Storage Module [1].

The algorithm of the Outflow Control Module [3] decreases the units continuously (e.g. x units in y hours) and acts independently of external or internal events. The speed is customer individually configurable derived from the subscription conditions data (for example a high mobile subvention leads to a higher speed in the degradation). For this purpose the network operator/service provider can use the external interface [G].

Info Push Module [4]

The Info Push Module [4] prepares and pushes information for the customer automatically through the external interface [C]. The data are fetched from the Leakage Bucket Storage Module [1] using the interface [b].

The subscriber will be informed about changes in his/her “Leakage Bucket” status e.g. transitions from one tariff representation to an other accordingly his individual settings (what kind of information, which presentation form) by SMS, USSD, WAP, Voice.

Info Access Module [5]

The Info Access Module [5] prepares and send information on demand of the customer or the customer care staff via the external interface [D]. The request can be based on i-mode™, the web, SMS, USSD, IVR and other appropriate transport mechanisms or services.

The implemented SW of the Info Access Module received the request, fetched the needed data via the internal interface [c] from the Leakage Bucket Storage Module [1] prepares the data specifically for the requested methods. The info for the customer shows the current status as well as the history and gives advices for future strategies for the usage of telecommunication services from the customer point of view.

Tariff Definition Module [6]

The Tariff Definition Module [6] prepares data for the present valid tariff for telecommunication services individually for the customer or group of customers based on the status of the counter in the Leakage Bucket Storage Module [1].

For this purpose the Tariff Definition Module fetches data from the Leakage Bucket Storage Module [1] via the interface [d] and supplies the external rating engine via the external interface [E]. Depend on the interface specification between the Leakage Bucket Infrastructure and the external rating engine the Tariff Definition Module supplies rough data for tariff calculation or the tariff for the requested telecommunication service.

Modification Access Module [7]

The Modification Access Module [7] allows the Service Provider/Network Operator via the external interface [F] the modification of certain parameters in the Leakage Bucket Storage Module [1] directly using the internal interface [e].

The Service Provider/Network Operator can realise certain loyalty and promotion champagnes by using this capability for example on the customer's birthday the counter in the Leakage Bucket Storage Module [1] can be set on a higher level that results in a better tariff for the customer.

1. System for dynamic tariffing of telecommunication services, the system comprising at least one computer, the at least one computer comprising
a leakage bucket storage module (1) for handling a current tariff variable (LB_C);
an inflow control module (2) for controlling the increase (LB_A) of the current tariff variable (LB_C);
an outflow control module (3) for controlling the decrease (LB_B) of the current tariff variable (LB_C);
the inflow control module (2) being arranged to communicate with the leakage bucket storage module (1) via a first interface (a) and the outflow control module (3) being arranged to communicate with the leakage bucket storage module (1) via a second interface (f).

2. System according to claim 1, wherein the inflow control module (2) comprises a third interface (A) to receive service information data and a fourth interface (B) to receive weighing parameters to weigh the service information data, the weighted service information data controlling the increase (LB_A) of the current tariff variable (LB_C).

3. System according to claim 2, wherein the outflow control module (3) comprises a fifth interface (G) to receive subscription conditions data, the subscription conditions data controlling the decrease (LB_B) of the current tariff variable (LB_C).

4. System according to claim 3, wherein the at least one computer further comprising a tariff definition module (6) for reading the current tariff variable (LB_C), the tariff definition module (6) being arranged to communicate with the leakage bucket storage module (1) via a sixth interface (d), the tariff definition module (6) further being arranged to communicate with an external rating engine via a seventh interface (E).

5. System according to claim 4, wherein the at least one computer further comprises a direct modification module (7) for directly setting the current tariff variable (LB_C) to a specific value, the direct modification module (7) being arranged to communicate with the leakage bucket storage module (1) via a eighth interface (e), the direct modification module (7) further being arranged to communicate with a service provider system via a ninth interface (F).

6. System according to claim 5, wherein the at least one computer further comprises an info push module (4) for preparing and pushing informative messages to a customer through a tenth interface (C), the info push module (4) being arranged to communicate with the leakage bucket storage module (1) via a eleventh interface (b).

7. System according to claim 6, wherein the at least one computer further comprises an info access module (5) for providing the current tariff variable (LB_C) when a request is received through a twelfth interface (D), the info access module (5) being arranged to communicate with the leakage bucket storage module (1) via a thirteenth interface (c).

8. Method for dynamic tariffing of telecommunication services in at least one computer comprising one or more modules, the method comprising the steps of
handling a current tariff variable (LB_C);
controlling the increase (LB_A) of the current tariff variable (LB_C);
controlling the decrease (LB_B) of the current tariff variable (LB_C).

9. Method according to claim 8, wherein using a weighted service information data for controlling the increase (LB_A) of the current tariff variable (LB_C).

10. Method according to claim 9, wherein using a subscription conditions data for controlling the decrease (LB_B) of the current tariff variable (LB_C).

11. Method according to claim 10, wherein reading and sending the current tariff variable (LB_C) to an external rating engine via a seventh interface (E).

12. Method according to claim 11, wherein directly setting the current tariff variable (LB_C) to a specific value.

13. Method according to claim 12, wherein preparing and pushing informative messages to a customer through a tenth interface (C).

14. Method according to claim 13, wherein providing the current tariff variable (LB_C) when a request is received through a twelfth interface (D).
